(19) United States
(12) Patent Application Publication
(10) Pub. No.: US 2017/0017328 A1
(43) Pub. Date: Jan. 19, 2017

(54) TOUCH DISPLAY PANEL AND FABRICATION THEREOF

(71) Applicant: InnoLux Corporation, Miao-Li County (TW)

(72) Inventors: Chia-Hao TSAI, Miao-Li County (TW); Jen-Chieh PENG, Miao-Li County (TW); Chih-Hao CHANG, Miao-Li County (TW); Bo-Feng CHEN, Miao-Li County (TW); Tung-Kai LIU, Miao-Li County (TW)

(21) Appl. No.: 15/212,079

(22) Filed: Jul. 15, 2016

Related U.S. Application Data
(60) Provisional application No. 62/193,787, filed on Jul. 17, 2015.

(30) Foreign Application Priority Data
Feb. 3, 2016 (TW) 105103450

(51) Int. Cl. G06F 3/041; G06F 3/044; H01L 27/12

(52) U.S. Cl. CPC G06F 3/0412; H01L 27/124; H01L 27/1259; G06F 3/044; G06F 2203/04103

(57) ABSTRACT

A touch display panel includes a substrate, a first metal layer, a second metal layer, common electrode pads, and a driving IC. The substrate includes a display area and a non-display area. The first metal layer disposed on the substrate includes gate lines and first metal wires, wherein the gate lines extend along a first direction. The second metal layer disposed on the substrate includes data lines and second metal wires, wherein the data lines extend along a second direction. The common electrode pads are disposed on the display area along the first direction and the second direction. The first metal wires and/or second metal wires are connected the common electrode pads and the driving IC. The first metal wires and/or second metal wires extend to the non-display area and extend to the display area along the first direction.

### CROSS REFERENCE TO RELATED APPLICATIONS

This application claims priority of U.S. Provisional Patent Application No. 62/193,787, filed on Jul. 17, 2015 and Taiwan Patent Application No. 105103450, filed on Feb. 3, 2016, the entirety of which is incorporated by reference herein.

### BACKGROUND OF THE INVENTION

Field of the Invention

The disclosure generally relates to a touch display panel technology, and more particularly, to a touch display panel technology to minimize the mura effect and improve touch performance.

Description of the Related Art

Touch display panels represent a new type of integrated display, having both a display function and a touch function. This new type of display is one of many new display types that have developed through the use of integrating display integrated circuits (IC) and touch ICs, and by adopting a new production process at liquid-crystal display (LCD) panel factories.

Touch display panels can be divided into the mutual-capacitance type and the self-capacitance type, depending on the means of transmission of the touch signal. In the mutual-capacitance type of touch display panel, the paths for sending the touch signal and receiving the touch signal are different. In the self-capacitance type of touch display panel, the paths for sending the touch signal and receiving the touch signal are the same. In one self-capacitance type of touch display panel, a common electrode (or ground electrode) is divided into a plurality of electrode pads in a matrix shape. In the display period, each of the electrode pads is utilized as a normal common electrode. But in the touch-control period, each of the electrode pads is utilized as a touch sensing electrode to determine the location of the touch object by detecting the capacitance between the electrode pad and the external touch object.

FIG. 1 is a top diagram of part of a touch display panel according to the prior art. As shown in FIG. 1, each of the common electrode pads S1, S2 . . . , and Sn is connected to a metal wire T1, T2, . . . , and Tn respectively through a plurality of holes. In the display period of the touch display panel, these metal wires T1, T2, . . . , and Tn will output a default voltage to make the common electrode pads S1, S2 . . . , and Sn maintain the same voltage level. In the touch-control period of the touch display panel, these metal wires T1, T2, . . . , and Tn will respectively output touch-sensing signals to sense whether each of the common electrode pads S1, S2 . . . , and Sn is touched.

In a conventional manufacturing process for a touch display panel, a metal layer (e.g. a M3 layer), which is used to transmit a sensing signal to the common electrode pads through the contact holes, is designed in the touch display panel to avoid any interference between the sensing signal, thin-film-transistor (TFT) elements, and data signal. The details are illustrated in FIG. 2.

FIG. 2 is a profile diagram of a touch display panel which is produced by the top-com manufacturing process according to the prior art. As shown in FIG. 2, the gate electrode (GE) layer 210 (can be regarded as M1 layer) is deposited and patterned first, and then the gate insulation (GI) layer 220 and active layer (or semiconductor layer) 230 are deposited and patterned, and then the GI layer 220 is excavated a contact hole to the GE layer 210. Then, the source/drain (SD) metal layer 240 is deposited (can be regarded as M2 layer) and patterned, wherein part of the SD metal layer 240 is connected to the GE layer 210 (for M1, M2 transfer). Then a first passivation (BP1) layer and Teflon polyperfluoro-alboxy fluoropolymer (PFA) layer 260 (flat layer) are deposited and patterned to excavate a contact hole to the SD metal layer 240. In addition, the ITO_pixel layer 270 is deposited, and then the ITO_pixel layer 270 is patterned to be a pixel electrode (layer) of the touch display panel and make the ITO_pixel layer 270 connected to a TFT drain terminal of the SD metal layer 240 through the contact hole, wherein the ITO means Indium Tin Oxide. Then, a second passivation (BP2) layer 280 is deposited. Then a metal layer 290 (can be regarded as M3 layer and the metal wires of the touch line) is deposited and patterned to cover on the data lines of the SD metal layer 240. Then, the third passivation (BP3) layer 295 is deposited and patterned to produce a contact hole on M3 Layer. Finally, ITO_Com layer 271 is deposited and patterned to form an ITO slit as the Com electrode of the touch display panel, and to connect to the M3 layer through the contact hole of the BP3 layer 295.

FIG. 3 is a schematic diagram of the layout of the metal wires of the touch display panel according to the prior art. As shown in FIG. 3, the electrode pads in a matrix shape are configured on the display area 11 of the substrate 10 and the driving IC which is shared by the voltage-level signals and touch-sensing signals is configured on the non-display area 12. The metal wires are extended in parallel along the row direction in the display area 11 and are connected to the driving IC in the circular-sector shape in the non-display area 12. In a conventional layout, for the metal wires connected to the electrode pads in the same column, the metal wire Tmax in the leftmost side is connected to the top electrode pad in the display area 11 such that the metal wire Tmax has the longest length in the display area 11. In addition, because the metal wire Tmax corresponds to the longest distance between the driving IC in the non-display area 12, the metal wire Tmax also has the longest length in the non-display area 12. Relatively speaking, for the metal wires connected to the electrode pads in the same column, the metal wire Tmin in the rightmost side is connected to the bottom electrode pad in the display area 11 such that the metal wire Tmin has the shortest length in the display area 11. In addition, because the metal wire Tmin corresponds to the nearest distance between the driving IC in the non-display area 12, the metal wire Tmin also has the shortest length in the non-display area 12.

Therefore, the different lengths of the metal wires may cause uneven RC loadings. If uneven RC loadings occur, this can easily cause the Mura effect to occur on the screen of the touch display panel, or cause the touch performance to worsen.

In addition, FIG. 4 is a schematic diagram of the parasitic capacitance of the touch display panel according to the prior art. As shown in FIG. 4, because there is more parasitic capacitance in the touch display panel, such as the capacitance Cxd between the common electrode pad S1 and the data lines, the capacitance Cxg between the common electrode pad S1 and the gate lines, the capacitance Cxv between the common electrode pad S1 and the common electrode pad S2, the capacitance Cld between the metal wire T1 and the data lines, the capacitance Clg between the metal wire T1 and the gate lines, and so on, it is hard to control the touch performance.

### BRIEF SUMMARY OF THE INVENTION

A touch display panel is provided to reduce the mura effect and improve touch performance, as mentioned above.

An embodiment of the disclosure provides a touch display panel. The touch display panel comprises a substrate, a first metal layer, a second metal layer, a plurality of common electrode pads, and a driving IC. The substrate comprises a display area and a non-display area, wherein the non-display area is disposed around the display area. The first metal layer is disposed on the substrate and comprises a plurality of gate lines and a plurality of first metal wires, wherein the plurality of gate lines extend along a first direction. The second metal layer is disposed on the substrate and comprises a plurality of data lines and a plurality of second metal wires, wherein the plurality of data lines extend along a second direction and the first direction is different from the second direction. The plurality of common electrode pads are disposed on the display area along the first direction and the second direction to define a pixel matrix. The driving IC is disposed on the non-display area. The plurality of first metal wires and/or the plurality of second metal wires are connected the common electrode pads and the driving IC. The plurality of first metal wires and/or the plurality of second metal wires extend to the non-display area and extend to the display area along the first direction.

In some embodiments of the disclosure, a plurality of metal wires in the display area comprise the first metal wires. In the display area, each of the common electrode pads is connected to corresponding first metal wires and/or second metal wires through at least one contact hole. In some embodiments of the disclosure, in the display area, each of the first metal wires and/or second metal wires partially overlaps the gate lines.

In some embodiments of the disclosure, the touch display panel is applied to a top-com manufacturing process or applied to a top-pixel manufacturing process.

An embodiment of the disclosure provides a method for a manufacturing process of a touch display panel. The method for the manufacturing process comprises the steps of producing a first metal layer on a substrate, wherein the first metal layer comprises a plurality of gate lines and a plurality of first metal wires; producing a first insulation layer on the first metal layer; producing a semiconductor layer, an pixel electrode layer and a second metal layer on the first insulation layer, wherein the second metal layer comprises a plurality of data lines and a plurality of second metal wires; producing a second insulation layer; and producing an common electrode layer on the second insulation layer, wherein the plurality of first metal wires and/or the plurality of second metal wires extend to a non-display area of the substrate and then extend to a display area of the substrate along a first direction corresponding to the plurality of gate lines of the display area.

Another embodiment of the disclosure provides a method for a manufacturing process of a touch display panel. The method for the manufacturing process comprises the steps of producing a first metal layer on a substrate, wherein the first metal layer comprises a plurality of gate lines and a plurality of first metal wires; producing a first insulation layer on the first metal layer; producing a semiconductor layer and a second metal layer on the first insulation layer, wherein the second metal layer comprises a plurality of data lines and a plurality of second metal wires; producing a second insulation layer; producing a third insulation layer on the second insulation layer; producing an common electrode layer on the third insulation layer; producing a fourth insulation layer on the common electrode layer; and producing an pixel electrode layer on the fourth insulation layer, wherein the plurality of first metal wires and/or the plurality of second metal wires extend to a non-display area of the substrate and then extend to a display area of the substrate along a first direction corresponding to the plurality of gate lines of the display area.

Other aspects and features of the disclosure will become apparent to those with ordinary skill in the art upon review of the following descriptions of specific embodiments of wireless communication methods and devices.

### BRIEF DESCRIPTION OF THE DRAWINGS

The disclosure will become more fully understood by referring to the following detailed description with reference to the accompanying drawings, wherein:

FIG. 1 is a top diagram of part of a touch display panel according to the prior art;

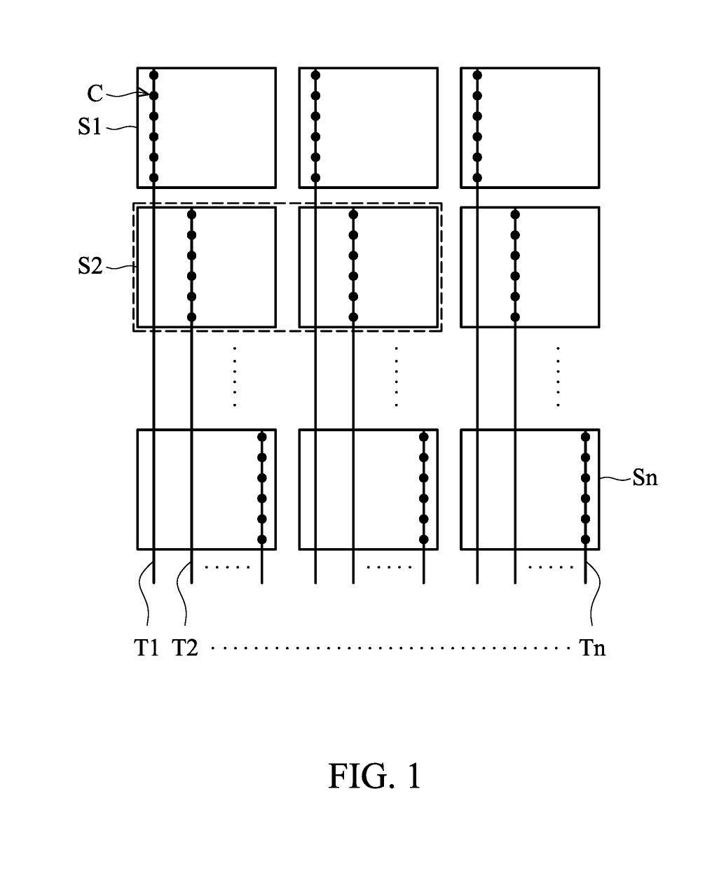

FIG. 2 is a profile diagram of a touch display panel which is produced by the top-com manufacturing process according to the prior art;

FIG. 3 is a schematic diagram of a layout of the metal wires of the touch display panel according to the prior art;

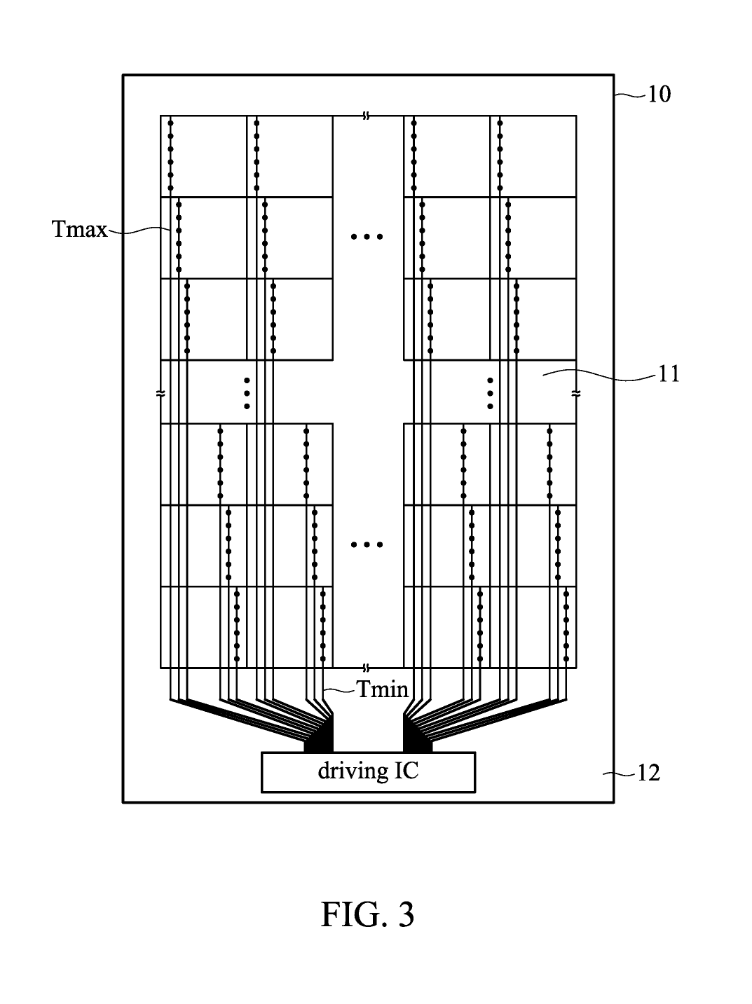

FIG. 4 is a schematic diagram of the parasitic capacitance of the touch display panel according to the prior art;

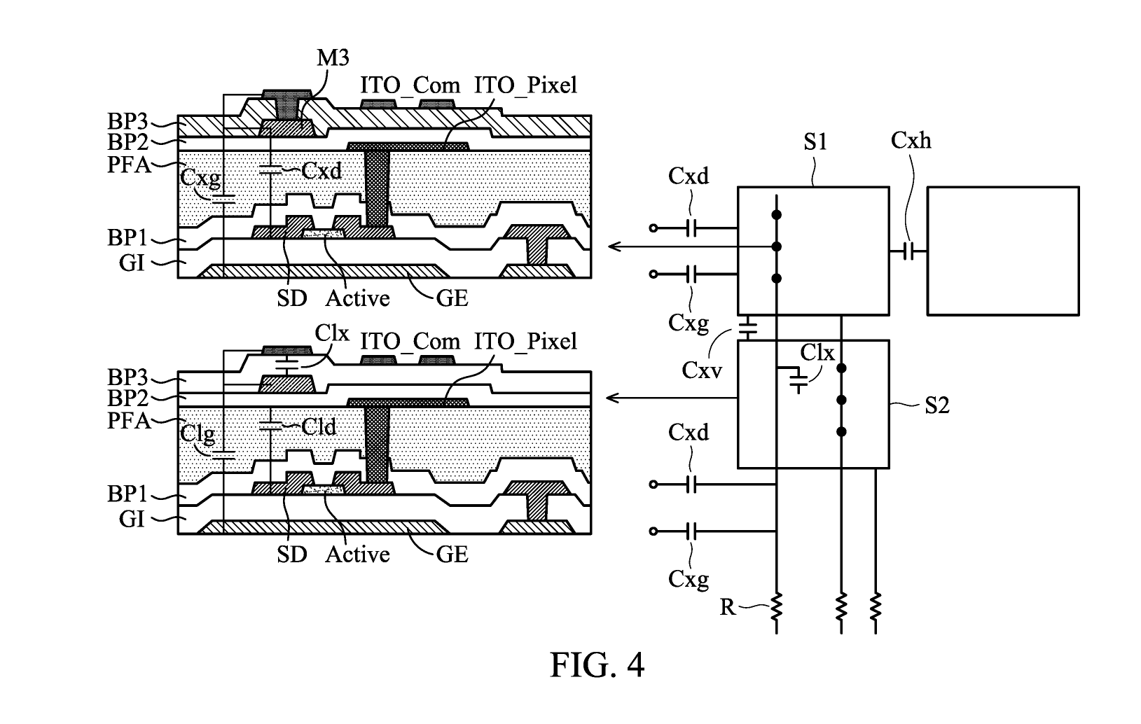

FIG. 5 is a block diagram of a touch display panel 100 according to an embodiment of the disclosure;

FIG. 6 is a profile diagram of the touch display panel 100 which is produced by the top-com manufacturing process according to an embodiment of the disclosure;

FIG. 7 is a profile diagram of the touch display panel 100 which is produced by the top-pixel manufacturing process according to an embodiment of the disclosure.

### DETAILED DESCRIPTION OF THE INVENTION

The following description is of the contemplated mode of carrying out the disclosure. This description is made for the purpose of illustrating the general principles of the disclosure and should not be taken in a limiting sense. The scope of the disclosure is determined by reference to the appended claims.

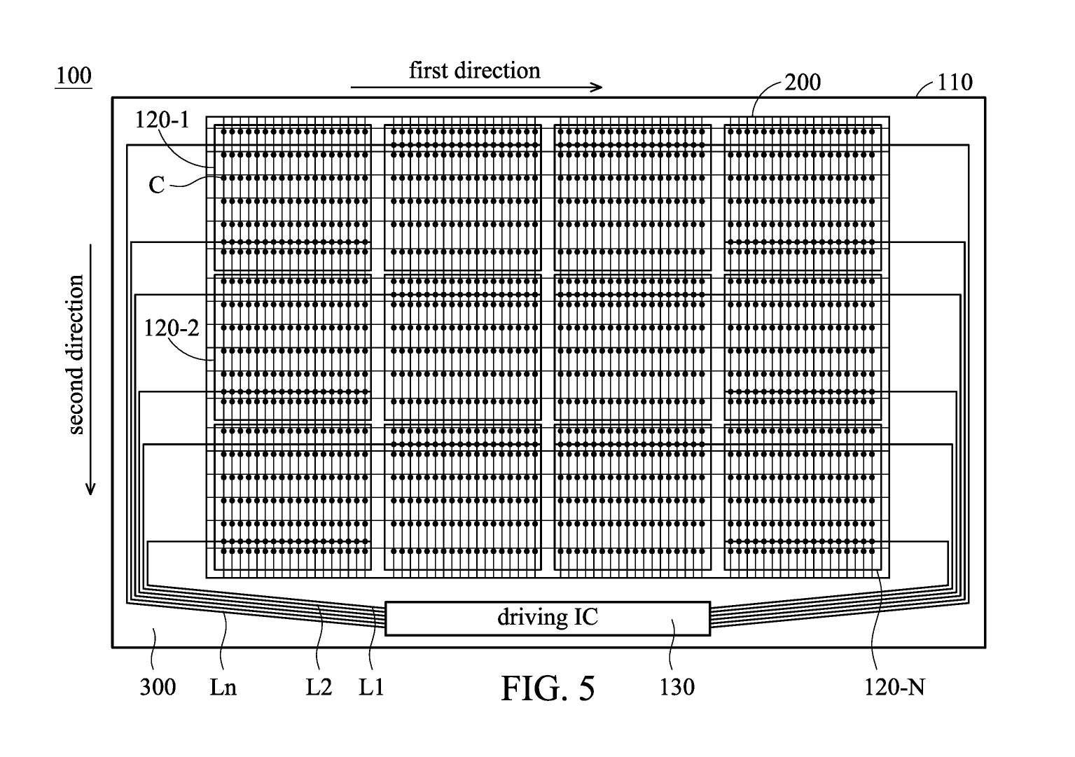

FIG. 5 is a block diagram of a touch display panel 100 according to an embodiment of the disclosure. The touch display panel 100 is a touch display panel with self-capacitance type, and it manufactured by the gate-on-panel (GOP) technology, i.e. in the manufacturing process of the touch display panel 100, the gate circuit will be configured in the Thin Film Transistor (TFT) array. As shown in FIG. 5, the touch display panel 100 comprise a substrate 110, a plurality of common electrode pads (or touch units) 120-1, 120-2 . . . 120-N, a driving IC 130 and a plurality of metal wires L1, L2, . . . Ln. Note that, in order to clarify the concept of the disclosure, FIG. 5 presents a simplified block diagram in which only the elements relevant to the disclosure are shown. However, the disclosure should not be limited to what is shown in FIG. 5.

As shown in FIG. 5, the substrate 110 comprises a display area 200 and a non-display area 300, wherein the non-display area 300 is disposed around the display area 200. In the display 200, the common electrode pads 120-1, 120-2 . . . 120-N, a plurality of gate lines and data lines are configured in the display 200. The gate lines extend along a first direction (e.g. a row direction), and the data lines extend along a second direction (e.g. a column direction) such that the gate lines and data lines are perpendicular to each other. The common electrode pads 120-1, 120-2 . . . 120-N are disposed in a matrix shape. Specifically, the common electrode pads 120-1, 120-2 . . . 120-N are disposed along the first direction and the second direction to produce a pixel matrix.

In an embodiment of the disclosure, the metal wires L1, L2, . . . Ln can be regarded as the Vcom lines and sensing lines, and they are connected to the common electrode pads 120-1, 120-2 . . . 120-N and driving IC 130 to provide Vcom signal and sensing signal to the common electrode pads 120-1, 120-2 . . . 120-N. In an embodiment of the disclosure, the metal wires L1, L2, . . . Ln extend from the driving IC 130 to the non-display area 300 and extend to the display area 200 along the first direction corresponding to the gate lines of the display area 200.

In an embodiment of the disclosure, the touch display panel 100 may be applied to the touch display panel produced by the top-com manufacturing process or applied to the touch display panel produced by the top-pixel manufacturing process. Details are illustrated bellow.

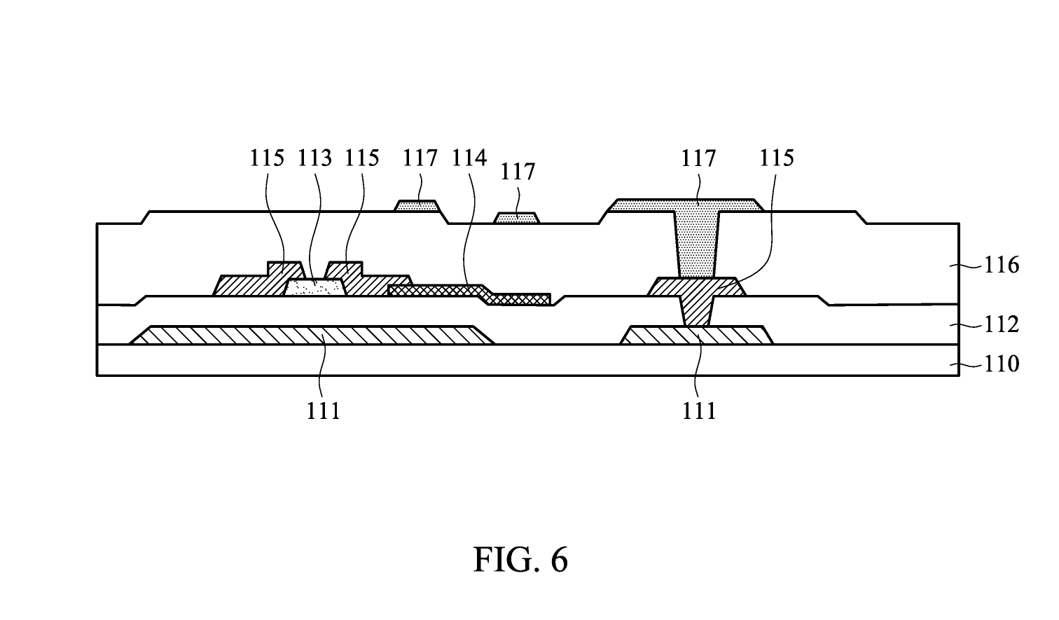

FIG. 6 is a profile diagram of the touch display panel 100 which is produced by the top-com manufacturing process according to an embodiment of the disclosure. As shown in FIG. 6, in the manufacturing process of the touch display panel 100, a first metal layer 111 is deposited on the substrate 110. In an embodiment of the disclosure, the first metal layer 111 comprises the gate electrode (GE) and gate lines. In addition, the first metal layer 111 further comprises a plurality of first metal wires (e.g. Vcom lines and sensing lines) to transmit the Vcom signal and the sensing signal. When the first metal layer 111 has been produced, a first insulation layer 112 will deposited on the metal layer 111, and a contact hole is excavated to the first metal layer 111 in the first insulation layer 112. The first insulation layer 112 can be regarded as a gate insulation layer. Then, an Active layer (or semiconductor layer) 113, an ITO_pixel layer 114 and a second metal layer 115 will be produced. The ITO_pixel layer 114 can be the pixel electrode (layer) of the touch display panel 100 after the ITO_pixel layer 114 is patterned. The second metal layer 115 comprises the source electrode, drain electrode and data lines. In addition, the second metal layer 115 further comprises a plurality of second metal wires. Then, a second insulation layer (e.g. a passivation (BP) layer) 116 will be produced, and a contact hole is excavated to the second metal layer 115 in the second insulation layer 116. Finally, an ITO_Com layer 117 is produced. The ITO_Com layer 117 can be the common electrode (layer) of the touch display panel 100, after the ITO_Com layer 117 is patterned.

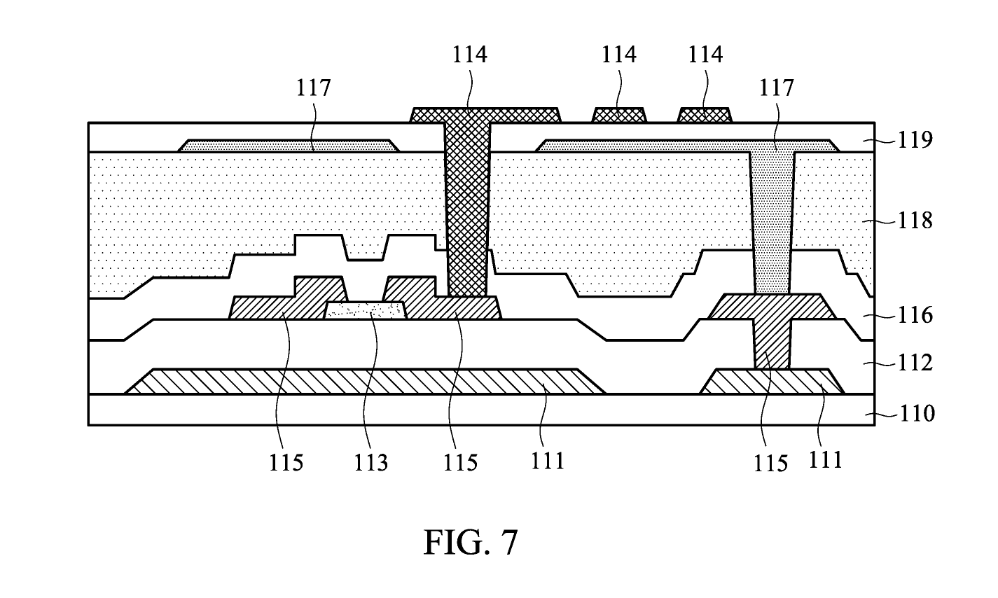

FIG. 7 is a profile diagram of the touch display panel 100 which is produced by the top-pixel manufacturing process according to an embodiment of the disclosure. As shown in FIG. 7, in the manufacturing process of the touch display panel 100, a first metal layer 111 is deposited on the substrate 110. In an embodiment of the disclosure, the first metal layer 111 comprises the gate electrode and gate lines. In addition, the metal layer 111 further comprises a plurality of first metal wires (e.g. Vcom lines and sensing lines) to transmit the Vcom signal and the sensing signal. When the first metal layer 111 has been produced, a first insulation layer 112 will deposited on the metal layer 111, and a contact hole is excavated to the first metal layer 111 in the first insulation layer 112. The first insulation layer 112 can be regarded as a gate insulation layer. Then, an Active layer (or semiconductor layer) 113, and a second metal layer 115 will be produced. The second metal layer 115 comprises the source electrode, drain electrode and data lines. In addition, the second metal layer 115 further comprises a plurality of second metal wires. Then, a second insulation layer 116 (e.g. a BP layer) and a third insulation layer 118 (e.g. a PFA layer) will be produced, and a contact hole is excavated to the second metal layer 115 in the second insulation layer 116 and the third insulation layer 118. Then, an ITO_Com layer 117 is produced. The ITO_Com layer 117 can be the common electrode (layer) of the touch display panel 100, after the ITO_Com layer 117 is patterned. Then, a fourth insulation layer 119 (e.g. a BP layer) is generated and a contact hole is excavated to the second metal layer 115 in the fourth insulation layer 119. Finally, an ITO_pixel layer 114 is produced. The ITO_pixel layer 114 can be the pixel electrode (layer) of the touch display panel 100 after the ITO_pixel layer 114 is patterned.

In an embodiment of the disclosure, when the metal wires L1, L2, . . . Ln are in the non-display area 300 (i.e. the metal wires L1, L2, . . . Ln has not extended to the display area 200), the metal wires L1, L2, . . . Ln in the non-display area 300 may comprise the plurality of first metal wires or the plurality of second metal wires. In another embodiment of the disclosure, when the metal wires L1, L2, . . . Ln are in the non-display area 300 (i.e. the metal wires L1, L2, . . . Ln has not extended to the display area 200), the metal wires L1, L2, . . . Ln in the non-display area 300 may comprise the plurality of first metal wires and the plurality of second metal wires.

In an embodiment of the disclosure, when the metal wires L1, L2, . . . Ln are in the display area 200, the metal wires L1, L2, . . . Ln in the display area 200 may comprise the plurality of first metal wires. In an embodiment of the disclosure, each of the common electrode pads 120-1, 120-2 . . . 120-N is connected to one of the corresponding first metal wires of the metal wires L1, L2, . . . Ln through at least one contact hole C. In an embodiment of the disclosure, each of the first metal wires may partially overlap with the gate line (e.g. the part (of one metal wire) which needs to transmit the sensing signal to common electrode pad).

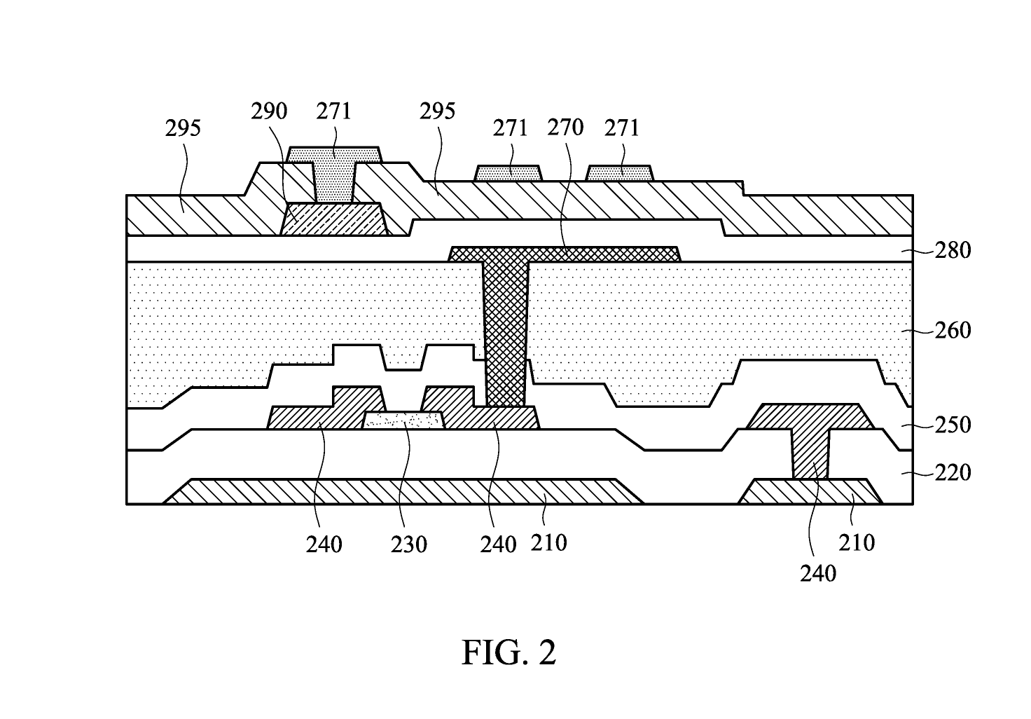

In the embodiments of the disclosure, the first metal layer and the second metal layer can replace the conventional M3 layer (as shown in FIG. 2). In the non-display area, the non-display area can comprise the metal wires of the first metal layer and/or the second metal layer (i.e. first metal wires and/or second metal wires) and in the display area, the display area can comprise the metal wires of the first metal layer (i.e. first metal wires). In addition, the metal wires may extend to the display area along the first direction of the gate lines, and then connect to the corresponding common electrode pads to transmit the Vcom signal and the sensing signal. According to the manufacturing processes and layouts of the touch display panel 100 provided in the embodiments of the disclosure, the length of the metal wires can be shortened, and the metal wires only need to extend half the length of the touch display panel 100, so the uneven RC loadings may be reduced, which may reduce the Mura effect and/or improve touch performance. In addition, because the metal wires do not need to be configured on the original M3 layer, the amount of parasitic capacitance, such as capacitance Clg, capacitance Cld, and capacitance Clx, can be decreased, to increase the touch uniformity.

It should be noted that, although not explicitly specified, one or more steps of the methods described herein can include a step for storing, displaying and/or outputting as required for a particular application. In other words, any data, records, fields, and/or intermediate results discussed in the methods can be stored, displayed, and/or output to another device as required for a particular application. While the foregoing is directed to embodiments of the disclosure, other and further embodiments of the disclosure can be devised without departing from the basic scope thereof. Various embodiments presented herein, or portions thereof, can be combined to create further embodiments. The above description is of the contemplated mode of carrying out the disclosure. This description is made for the purpose of illustrating the general principles of the disclosure and should not be taken in a limiting sense. The scope of the disclosure is determined by reference to the appended claims.

The above paragraphs describe many aspects. Obviously, the teaching of the disclosure can be accomplished by many methods, and any specific configurations or functions in the disclosed embodiments only present a representative condition. Those who are skilled in this technology will understand that all of the disclosed aspects in the disclosure can be applied independently or be incorporated.

While the disclosure has been described by way of example and in terms of embodiment, it is to be understood that the disclosure is not limited thereto. Those who are skilled in this technology can still make various alterations and modifications without departing from the scope and spirit of this disclosure. Therefore, the scope of the present disclosure shall be defined and protected by the following claims and their equivalents.

What is claimed is:

1. A touch display panel, comprising:
a substrate, comprising a display area and a non-display area, wherein the non-display area is disposed around the display area;
a first metal layer, disposed on the substrate, and comprising a plurality of gate lines and a plurality of first metal wires, wherein the plurality of gate lines extend along a first direction;
a second metal layer, disposed on the substrate, and comprising a plurality of data lines and a plurality of second metal wires, wherein the plurality of data lines extend along a second direction and the first direction is different from the second direction;
a plurality of common electrode pads, disposed on the display area along the first direction and the second direction to define a pixel matrix; and
a driving IC, disposed on the non-display area;
wherein the plurality of first metal wires and/or the plurality of second metal wires are connected the common electrode pads and the driving IC,
wherein the plurality of first metal wires and/or the plurality of second metal wires extend to the non-display area and extend to the display area along the first direction.

2. The touch display panel of claim 1, wherein a plurality of metal wires in the display area comprise the first metal wires.

3. The touch display panel of claim 2, wherein in the display area, each of the common electrode pads is connected to the corresponding first metal wires of the metal wires through at least one contact hole.

4. The touch display panel of claim 2, wherein in the display area, each of the first metal wires partially overlaps the gate lines.

5. The touch display panel of claim 1, wherein the touch display panel is applied to a top-com manufacturing process or applied to a top-pixel manufacturing process.

6. A method for a manufacturing process of a touch display panel, comprising:
producing a first metal layer on a substrate, wherein the first metal layer comprises a plurality of gate lines and a plurality of first metal wires;
producing a first insulation layer on the first metal layer;
producing a semiconductor layer, a pixel electrode layer and a second metal layer on the first insulation layer, wherein the second metal layer comprises a plurality of data lines and a plurality of second metal wires;
producing a second insulation layer; and
producing an common electrode layer on the second insulation layer,
wherein the plurality of first metal wires and/or the plurality of second metal wires extend to a non-display area of the substrate and then extend to a display area of the substrate along a first direction corresponding to the plurality of gate lines of the display area.

7. The manufacturing process method of claim 6, wherein a plurality of metal wires in the display area comprise the first metal wires.

8. A manufacturing process method of a touch display panel, comprising:
producing a first metal layer on a substrate, wherein the first metal layer comprises a plurality of gate lines and a plurality of first metal wires;
producing a first insulation layer on the first metal layer;
producing a semiconductor layer and a second metal layer on the first insulation layer, wherein the second metal layer comprises a plurality of data lines and a plurality of second metal wires;
producing a second insulation layer;
producing a third insulation layer on the second insulation layer;
producing a common electrode layer on the third insulation layer;
producing a fourth insulation layer on the common electrode layer; and
producing a pixel electrode layer on the fourth insulation layer,
wherein the plurality of first metal wires and/or the plurality of second metal wires extend to a non-display area of the substrate and extend to a display area of the substrate along a first direction corresponding to the plurality of gate lines of the display area.

9. The manufacturing process method of claim 8, wherein a plurality of metal wires in the display area comprise the first metal wires.
